(19) United States
(12) Patent Application Publication
(10) Pub. No.: US 2009/0302917 A1
(43) Pub. Date: Dec. 10, 2009

(54) DELAY CIRCUIT AND TEST METHOD FOR DELAY CIRCUIT

(75) Inventor: Koji OKAMOTO, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/541,211

(22) Filed: Aug. 14, 2009

Related U.S. Application Data
(63) Continuation of application No. PCT/JP2007/000232, filed on Mar. 16, 2007.

(51) Int. Cl. H03K 5/13

(52) U.S. Cl. 327/231

(57) ABSTRACT

A delay circuit includes: a delay unit configured to delay an input signal and output the delayed signal; a selecting unit configured to select a first signal at the time of a normal operation or a second signal at the time of a test operation, and provide the selected signal to the delay unit; an inverting unit configured to invert an output signal of the delay unit, and output the inverted signal as the second signal; and a counting unit configured to count an output waveform of the delay unit.

### CROSS-REFERENCE TO RELATED APPLICATION

This application is a continuation of PCT application No. PCT/JP2007/000232, filed on Mar. 16, 2007, the entire contents of which are incorporated herein by reference.

### FIELD

The present invention relates to a delay circuit, and a test method for the delay circuit.

### BACKGROUND

FIG. 1 is an explanatory view of a test method for a delay line (delay circuit) having a delay value that can be selectively set. Namely, a delay line 4 is configured with a logic gate, etc. within an LSI as illustrated in FIG. 1, and mainly used to synchronize various types of signals by setting of a required delay time. The delay time of the delay line depends on a use application. Therefore, in order to recognize a delay time characteristic by pre-testing the delay time of the delay line provided within the LSI, conventionally, following configuration is proposed. Test terminals 2 and 6 are provided on input and output sides, respectively. A test signal 1 having a predetermined waveform is input from the terminal 2 on the input side and applied to the delay line 4 via a buffer amplifier 3 on the input side. The signal output from the delay line 4 is extracted from the test terminal 6 on the output side after amplified by a buffer amplifier 5 on the output side. The extracted signal waveform 7 is observed with a certain observer, and the delay time characteristic is verified with an AC test. In this way, the delay line is tested in an AC manner as illustrated in FIG. 1.

In the meantime, since many phase adjustments have been needed within a circuit in recent LSI implementations, a plurality of delay lines are included in the LSI. As a result, the number of probe terminals for observing an output waveform significantly increases in order to test all the included delay lines as in the above described method. Also a test time increases since an AC measurement is made a plurality of times by varying a delay value. Accordingly, a delay line test is omitted without being conducted in many cases, and an analysis cannot be made at the time of a fault occurrence if probe terminals are not provided.

### SUMMARY

A delay circuit according to one aspect of the invention includes: a delay unit configured to delay an input signal and output the delayed signal; a selecting unit configured to select a first signal at the time of a normal operation or a second signal at the time of a test operation, and provide the selected signal to the delay unit; an inverting unit configured to invert an output signal of the delay unit, and output the inverted signal as the second signal; and a counting unit configured to count an output waveform of the delay unit.

A test method according to another aspect of the invention for a delay circuit having a delay element for delaying and outputting an input signal, and a selector for selecting a first signal at the time of a normal operation and a second signal at the time of a test operation and for providing the selected signal to the delay element, includes: setting a delay time of the delay element; selecting the second signal by the selector; generating an oscillation waveform by inverting an output signal of the delay element, and by providing the inverted signal as the second signal; and counting the oscillation waveform.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an explanatory view of a test method for a delay line having a delay value that can be selectively set;

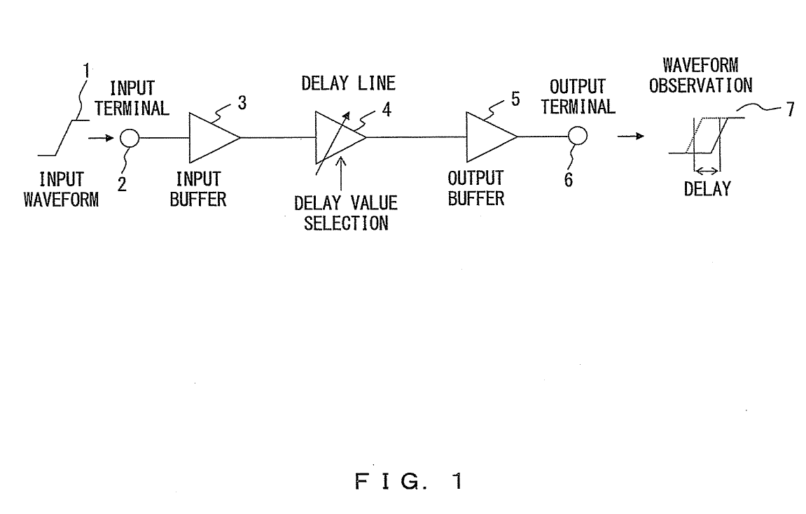

FIG. 2 is an explanatory view of a delay circuit and a test method for the delay circuit according to a first embodiment;

FIG. 3 illustrates a table that represents a relationship between a counter input cycle and a counter value with respect to delay line value according to the first embodiment;

FIG. 4 is a timing chart in the test method for the delay circuit according to the first embodiment;

FIG. 5 is an explanatory view of a delay circuit and a test method for the delay circuit according to a second embodiment;

FIG. 6 illustrates a table that represents a relationship between a counter enable cycle and a counter value with respect to delay line value according to the second embodiment;

FIG. 7 is a timing chart in the test method for the delay circuit according to the second embodiment;

FIG. 8 illustrates a modification example of the delay line according to the embodiments;

FIG. 9 illustrates another modification example of the delay line according to the embodiments;

FIG. 10 illustrates a specific configuration example of a capacitance value selecting unit illustrated in FIG. 9;

FIG. 11 illustrates another modification example of the capacitance value selecting unit illustrated in FIG. 9;

FIG. 12 illustrates a configuration example where a plurality of delay lines according to the embodiments are included in an LSI; and

FIG. 13 illustrates an operational sequence for switching between a normal operation and a test operation of the delay circuit according to the embodiments.

### DESCRIPTION OF EMBODIMENTS

Embodiments according to the present invention are described in detail below with reference to the drawings.

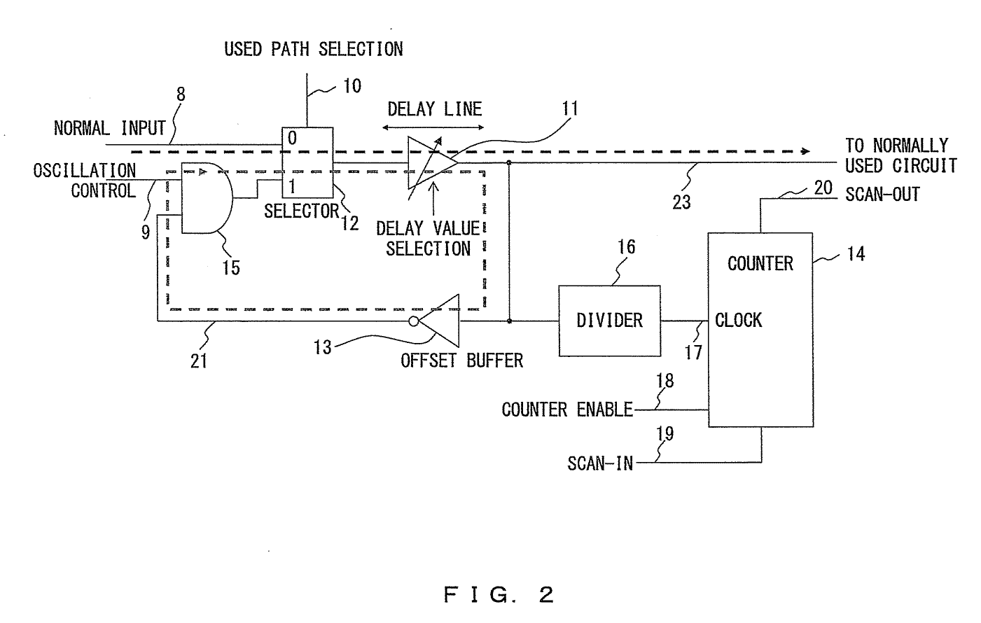

FIG. 2 is an explanatory view of a delay circuit and a test method for the delay circuit according to a first embodiment. As illustrated in FIG. 2, the delay circuit according to the first embodiment is configured to include at least a delay line 11, a selector 12, an inverter (offset buffer) 13, a counter 14, an AND circuit 15, and a divider 16. The delay line 11 delays an input signal and outputs the delayed signal. The selector 12 selects either of a normal input signal (first signal) 8 at the time of a normal operation or a test input signal (second signal) 21 at the time of a test operation. The inverter 13 inverts the output signal of the delay line 11 and outputs the inverted signal as the test input signal 21 at the time of the test operation. The counter 14 counts the output waveform of the delay line 11. The AND circuit 15 controls whether the test input signal 21 is to be provided to the selector 12 in accordance with a control signal 9. The divider 16, which is provided at the input side of the counter 14 in order to handle a wide delay time range of the delay line 11, divides the output signal of the delay line 11.

The counter 14 has a clock input terminal 17, to which the output signal of the delay line 11 is provided, and counts the output waveform of the delay line 11. The count value of the counter 14 is read out with scan-in 19 and scan-out 20 of the counter 14. The inverter (offset buffer) 13 is implemented in a path for the test input signal 21 in order to enable the measurement of a very small delay line. The delay line 11 is configured to be able to select a desired delay value.

A test of the delay circuit according to the first embodiment is described next. At the time of the test operation, a used path selection signal 10 is applied to the selector 12 to switch the selector 12 from a state where a normal input terminal (0) is selected to a state where a test input terminal (1) is selected. That is, the selector 12 selects a signal from the AND circuit 15 during the test mode. Next, when a control signal (oscillation control signal) 9 is applied to one input terminal of the AND circuit 15, the output signal of the delay line 11 is looped to the input terminal of the delay line 11 via the offset buffer 13, the other input terminal of the AND circuit 15, and the selector 12. As a result of setting of this looped path, an oscillation circuit is formed. When the oscillation circuit starts to oscillate, the divider 16 starts to divide the output signal of the delay line 11, and a counter enable terminal 18 is made active to start a count operation of the counter 14. By setting the duration of the count enable signal to a certain value, the counter 14 is caused to perform the count operation for the duration of the counter enable signal. That is, the counter 14 counts the signal from the oscillation circuit (or the divided signal) during the count enable terminal 18 is active. Then the count value is read out by performing a scan-out operation upon termination of the count operation performed by the counter 14.

If the delay time of the delay line 11 is very small (for example, several tens of ps), it is difficult to form the oscillation circuit. Therefore, the oscillation circuit is formed by increasing the delay time with the offset buffer 13 implemented in the path for the signal 21. If the delay time of the delay line 11 is able to vary broadly (for example, from several tens of ps to several ns), the divider 16 is arranged, and the number of bits of the counter and a clock input cycle are set to suitable values.

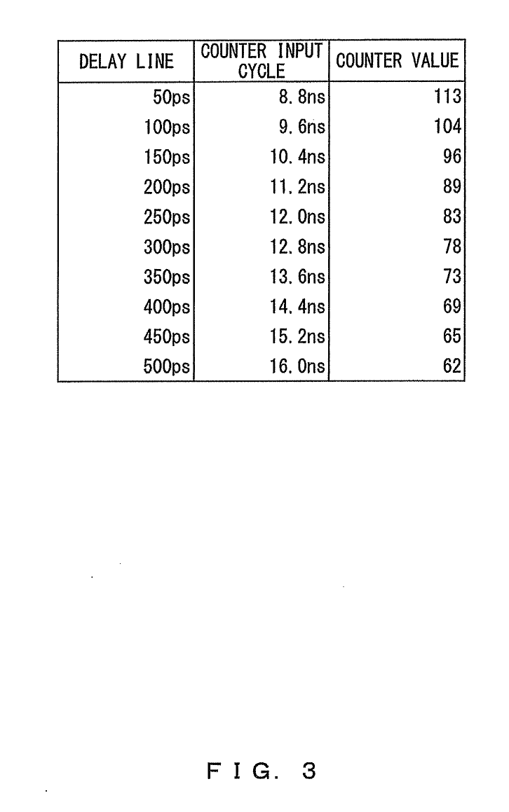

FIG. 3 is a table that represents a relationship between a counter input cycle and a counter value with respect to delay line value, which are obtained by executing the test method for the delay circuit according to the first embodiment. One case where the delay line value is 50 ps in the table illustrated in FIG. 3 is described. Here, assume that a delay time provided by the offset buffer is 500 ps, the dividing ratio of the divider 16 is 1/8, and the counter is an 8-bit counter. In this case, the counter input cycle results in (500+50)*2*8=8800 ps=8.8 ns. In addition, it is assumed that the duration of the counter enable signal is 1.0 μs. In this case, the counter value results in “113” (since 1000/8.8=113.6363 . . . ). By making the scan-out 20 for this counter value, the delay line is tested in a functional manner. Specifically, if the scan-out counter value is “113”, then the delay line 11 is estimated “50 ps”. That is to say, when the delay line 11 is set up with “50 ps” and the scan-out counter value is “113”, then it is recognized that the delay line 11 is correctly implemented. On the other hand, when the delay line 11 is set up with “50 ps” and the scan-out counter value is different from “113”, then it is recognized that the delay line 11 may contain some kind of faults.

The example where the delay line value is 50 ps has been described above. However, the counter input cycle and the counter value may be similarly obtained also for other delay line values. Additionally, the state of the delay line can be indirectly observed by determining that a predicted count value is not obtained for a corresponding delay value, whereby an analysis at the time of a fault occurrence is easily made.

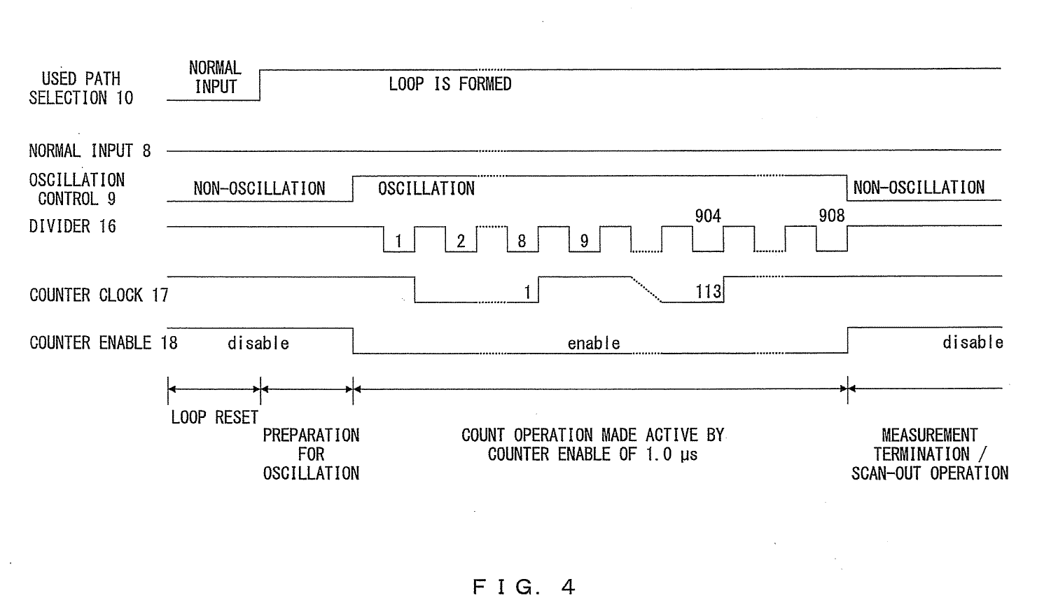

FIG. 4 is a timing chart in the case where the delay line value is 50 ps in the test method for the delay circuit according to the first embodiment. When the used path selection signal 10 indicates the normal input in FIG. 4, this is the state of a loop reset, namely, a non-oscillation state. If the used path selection signal 10 is switched from the normal operation mode to the test mode, the loop is formed. After being switched, the oscillation circuit is preparing for oscillation for awhile, and starts to be oscillated by an input of the oscillation control signal 9 to one of the inputs of the AND circuit 15. The output signal of the oscillation circuit is provided to the divider 16, and the output signal of the divider 16 (that is, divided signal of the oscillation circuit) is provided to the clock input terminal 17 of the counter 14. While the divided signal is provided to the counter 14, the counter enable signal of 1.0 μs is applied to the counter enable terminal 18 of the counter 14. By so doing, the counter 14 starts the count operation. In this case, the count value upon termination of the counter enable signal results in “113”, and this count value is read out with the scan-out operation. If the oscillation control signal is controlled to be synchronous with the counter enable signal, also the oscillation of the oscillation circuit terminates upon termination of the counter enable signal.

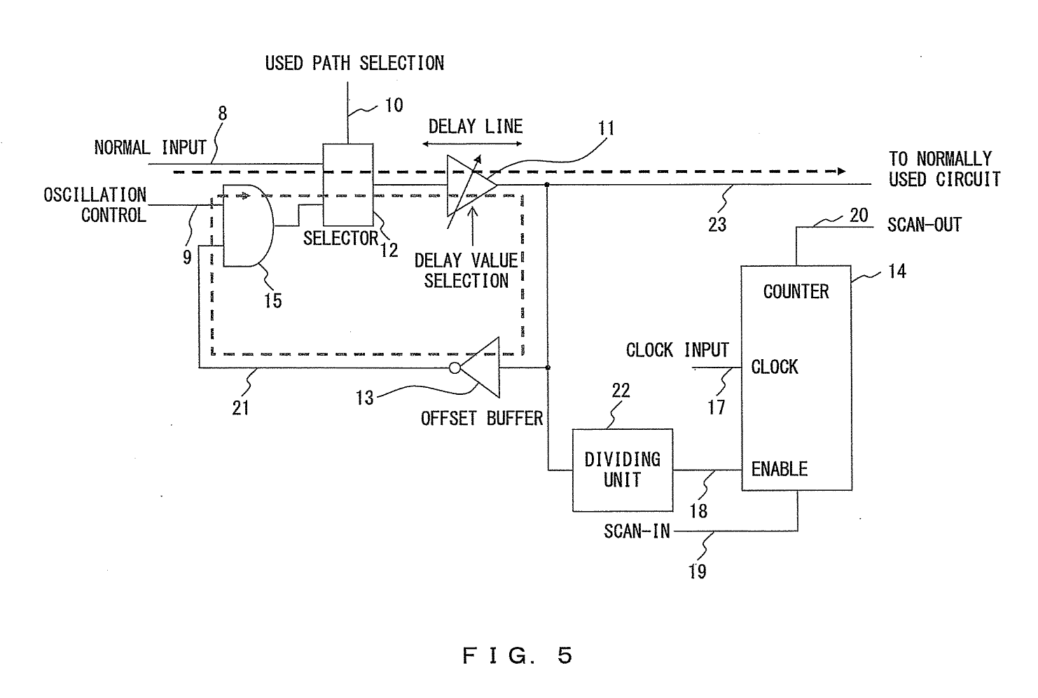

FIG. 5 is an explanatory view of a delay circuit and a test method for the delay circuit according to a second embodiment. As illustrated in FIG. 5, the delay circuit according to the second embodiment is configured to include at least a delay line 11, a selector 12, an inverter (offset buffer) 13, a counter 14, an AND circuit 15, and a dividing unit 22. The delay line 11 delays an input signal and outputs the delayed signal. The selector 12 selects either of a normal input signal 8 at the time of a normal operation or a test input signal 21 at the time of a test operation. The inverter 13 inverts the output signal of the delay line 11 and outputs the inverted signal as the test input signal 21 at the time of the test operation. The counter 14 counts the output waveform of the delay line 11. The AND circuit 15 controls whether the test input signal 21 is to be provided to the selector 12 in accordance with a control signal 9. The dividing unit 22, which is provided at the input side of the counter 14 in order to handle a wide delay time range of the delay line 11, divides the output signal of the delay line 11. The dividing unit 22 is realized by, for example, a divider or a counter.

The counter 14 for counting the output waveform of the delay line 11 has a clock input terminal 17 and a counter enable terminal 18. A clock signal with a predetermined cycle is provided to the clock input terminal 17, and the output signal of the delay line (or the divided signal) 11 is provided to the counter enable terminal 18. The counter 14 counts up the clock signal during the period when the counter enable signal is active at the counter enable terminal. By so doing, the counter 14 counts the output waveform of the delay line 11. The count value of the counter 14 is read out with scan-in 19 and scan-out 20 of the counter 14. The inverter (offset buffer) 13 is implemented in a path for the test input signal 21 in order to enable the measurement of a very small delay line. The delay line 11 is configured to be able to select a delay value.

A test of the delay circuit according to the second embodiment is described next. At the time of the test operation, a used path selection signal 10 is applied to the selector 12 to switch the selector 12 from a normal input side to a test signal input side. That is, the selector 12 selects a signal from the AND circuit 15 during the test operation. Next, when a control signal (oscillation control signal) 9 is applied to one input terminal of the AND circuit 15, the output signal of the delay line 11 is looped to the input terminal of the delay line 11 via the offset buffer 13, the other input terminal of the AND circuit 15, and the selector 12. As a result of setting of this looped path, an oscillation circuit is formed. When the oscillation circuit starts to oscillate, the dividing unit 22 starts to divide the output signal of the delay line 11, and a counter enable signal is made active to start a count operation of the counter 14. The count enable terminal 18 is made active for a predetermined time period. During this period, the counter 14 counts up the clock signal input to the clock input terminal. In response to the termination of the count enable signal, the count value is read out by performing a scan-out operation.

If the delay time of the delay line 11 is very small (for example, several tens of ps), it is difficult to form the oscillation circuit. Therefore, the oscillation circuit is formed by increasing the delay time with the offset buffer 13 implemented in the path for the signal 21. If the delay time of the delay line 11 is able to vary broadly (for example, from several tens of ps to several ns), a time period that the count enable signal is active is adjusted by implementing the dividing unit 22, and a clock signal with a predetermined cycle is input to the clock input terminal of the counter 14. In addition, the number of bits of the counter is set to suitable values.

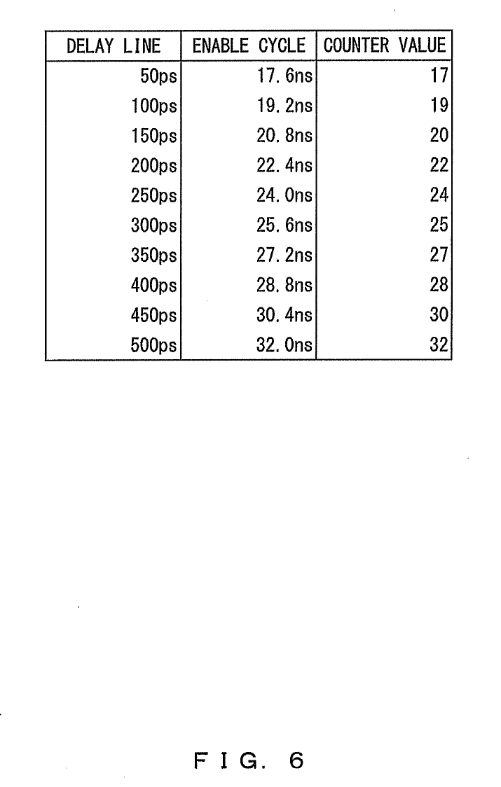

FIG. 6 illustrates a table that represents a relationship between the counter enable cycle and the counter value with respect to delay line value, which are obtained by executing the test method for the delay circuit according to the second embodiment. The case where the counter enable cycle results in 17.6 ns when the delay line value is 50 ps in the table illustrated in FIG. 6 is described. Here, assume that a delay provided by the offset buffer is 500 ps, the dividing ratio of the dividing unit 22 is 1/16, and the counter clock is 1.0 GHz. In this case, the counter enable cycle results in (500+50)*2*16=17600 ps=17.6 ns. The counter 14 counts up the counter clock of 1.0 GHz within the counter enable cycle of 17.6 ns, thus, the counter value “17” is obtained. By making the scan-out 20 for this counter value, the delay line is tested in a functional manner. Specifically, if the scan-out counter value is “17”, then the delay line 11 is estimated “50 ps”. That is to say, when the delay line 11 is set up with “50 ps” and the scan-out counter value is “17”, then it is recognized that the delay line 11 is correctly implemented.

The example where the delay line value is 50 ps has been described above. However, the enable cycle and the counter value can be similarly obtained also for other delay line values. Additionally, the state of the delay line can be indirectly observed by determining that a predicted count value is not obtained for a corresponding delay value, whereby an analysis at the time of a fault occurrence is easily made.

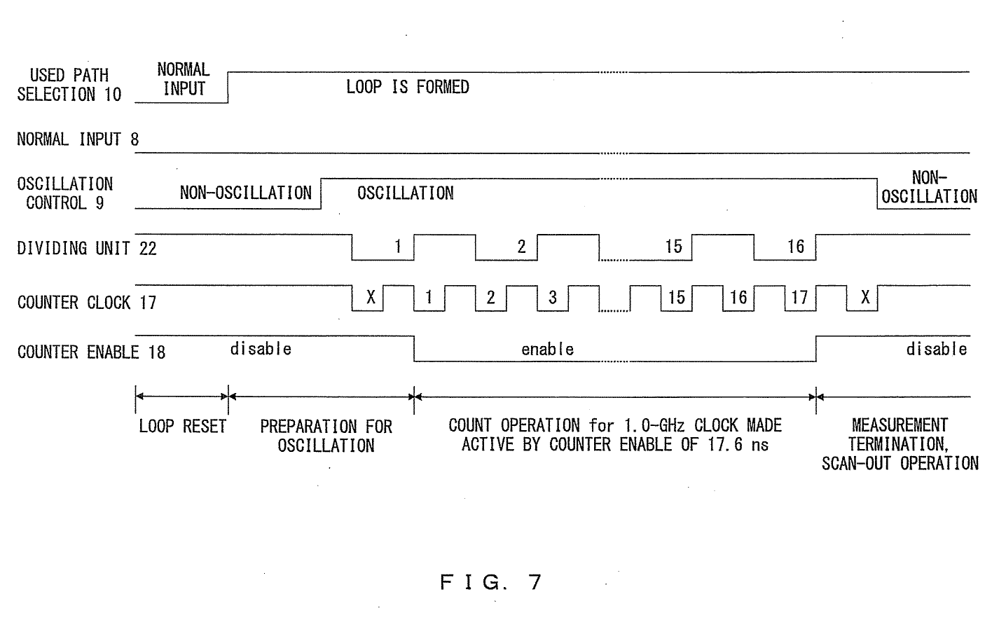

FIG. 7 is a timing chart in the case where the delay line value is 50 ps in the test method for the delay circuit according to the second embodiment. When the used path selection signal 10 indicates the normal input in FIG. 7, this is the state of a loop reset, namely, a non-oscillation state. If the used path selection signal 10 is switched from the normal operation mode to the test mode, the loop is formed. After being switched, the oscillation circuit is preparing for oscillation for awhile, and starts to be oscillated by an input of the oscillation control signal 9 to one of the inputs of the AND circuit 15. At the same time, the dividing unit 22, which is realized by a divider, a counter, etc., divides the output signal of the oscillation circuit, and the counter enable signal is applied to the counter enable terminal 18 in accordance with the output signal of the dividing unit 22. The counter 14 starts to count a clock signal applied to the clock input terminal during the count enable terminal is active. For example, when the dividing unit 22 processes 16 pulses, namely, 17.6 ns has elapsed, the counter enable signal is terminated. During this period, the counter 14 counts the clock signal of 1.0 GHz. Therefore, the count value results in “17”, and this count value is read out with the scan-out operation. The oscillation control signal 9 is applied before the dividing unit 22 starts to divide the output signal of the delay line 11 after the loop is formed, and stopped after the counter enable signal is terminated.

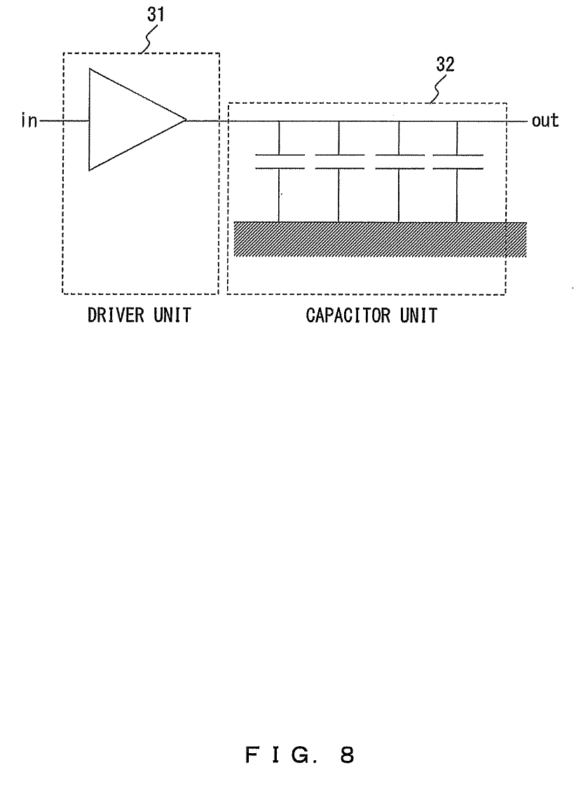

FIG. 8 illustrates a modification example of the delay line in the delay circuit according to the above described embodiments. In FIG. 8, a delay unit is configured to include a driver unit 31 for driving a signal, and a capacitor unit 32 for deforming and delaying the waveform of the signal from the driver unit 31 in accordance with the size (or quantity) of the capacitor, as a replacement for or as one example of the delay line 11 illustrated in FIGS. 2 and 5. In the example illustrated in FIG. 8, four capacitors are connected in parallel. However, the number of capacitors may be any number as far as the number is equal to or larger than one.

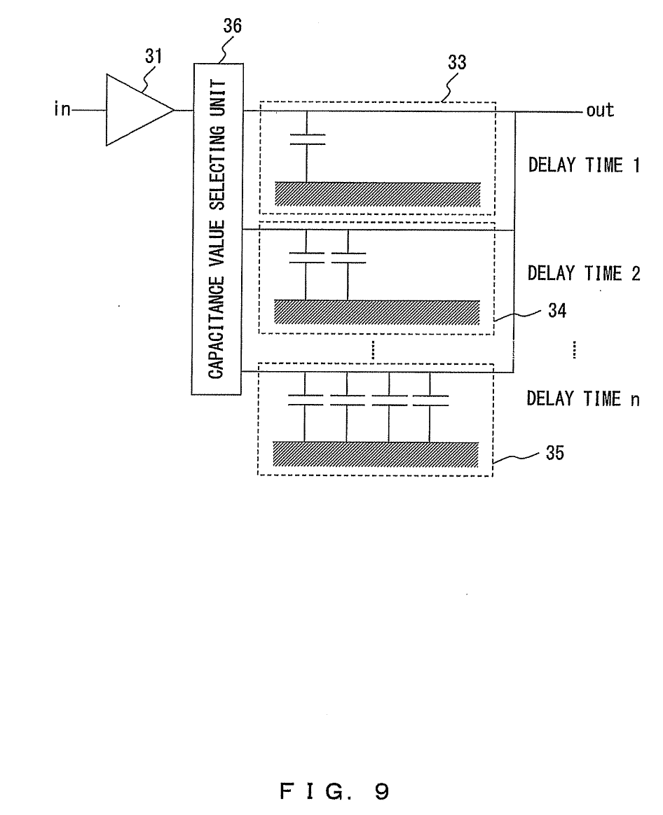

FIG. 9 illustrates another modification example of the delay unit. The delay unit illustrated in FIG. 9 includes the driver unit 31 for driving a signal, a plurality of capacitor units 33 to 35 having different capacitance. This delay unit is configured to generate a different delay time by selecting from among the plurality of capacitor units 33 to 35 with a capacitance value selecting unit 36 (equivalent to the delay value selection in FIGS. 2 and 5).

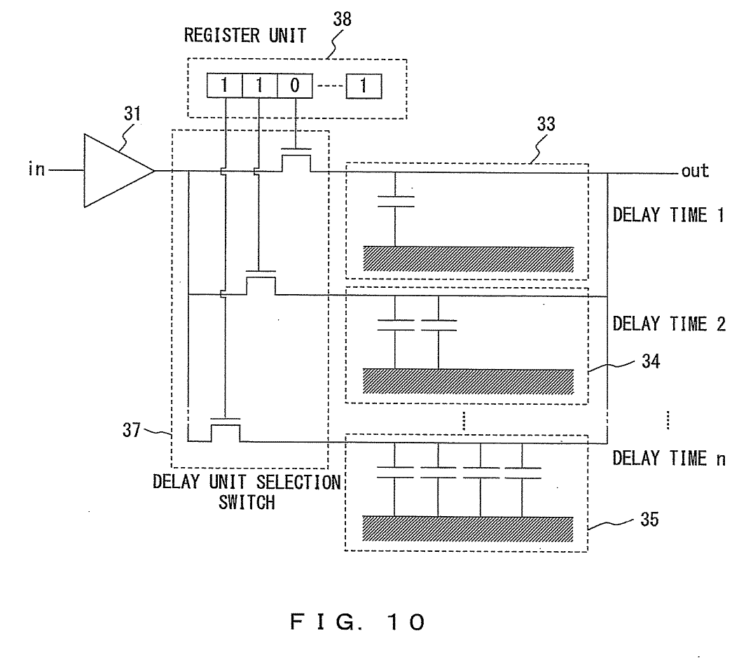

FIG. 10 illustrates a specific configuration example of the capacitance value selecting unit illustrated in FIG. 9. In FIG. 10, the capacitance value selecting unit 36 illustrated in FIG. 9 is configured to include a selection switch 37 for selecting a delay unit to be used, and a register unit 38 for selecting a switch element in the selection switch 37 to operate in accordance with a stored value (selection data). Each switch element of the selection switch 37 is realized by, for example, a PMOSFET, and configured so that a value stored by the register unit 38 is applied to the gate of the PMOSFET. In the example illustrated in FIG. 10, “0” stored by the register unit 38 is applied to the gate of the PMOSFET corresponding to the delay unit 33, thus the delay unit 33 is selected. In this case, “delay time 1” is generated by the delay unit.

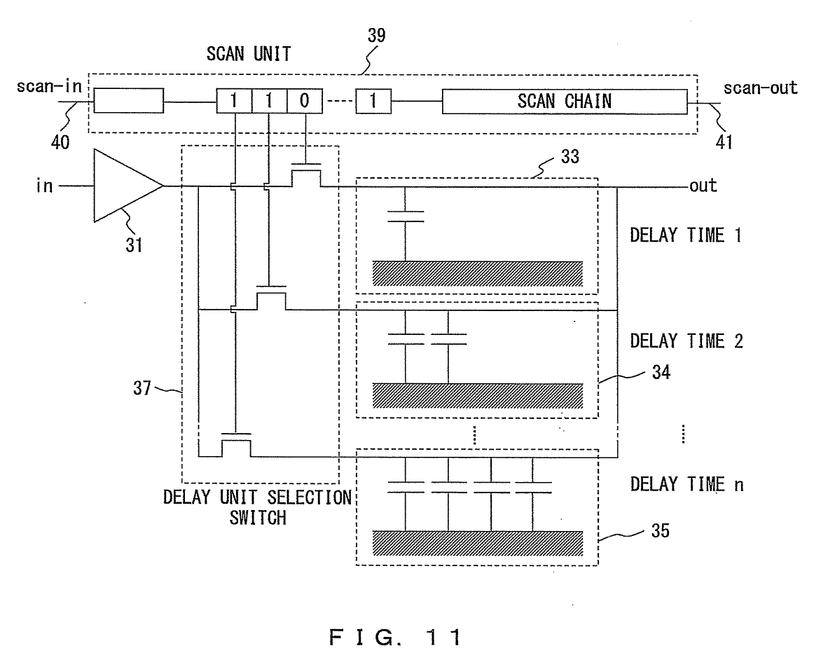

FIG. 11 illustrates a further modification example of the delay unit. The delay unit illustrated in FIG. 10 is configured so that a value for selecting a capacitance value is provided by a scan unit 39 in which a register value is shifted with a scan method. Namely, in FIG. 11, the value for selecting a capacitance value is input to the scan unit 39 with the scan-in 40 to form a scan chain, and the scan-out 41 is performed. As a result, the value for selecting a capacitance value is set/changed with the scan method, whereby a capacitance value may be selected with scan data. In addition, each delay value (delay time 1, 2, . . . , n) is sequentially tested while the data stored in the scan unit 39 is shifted.

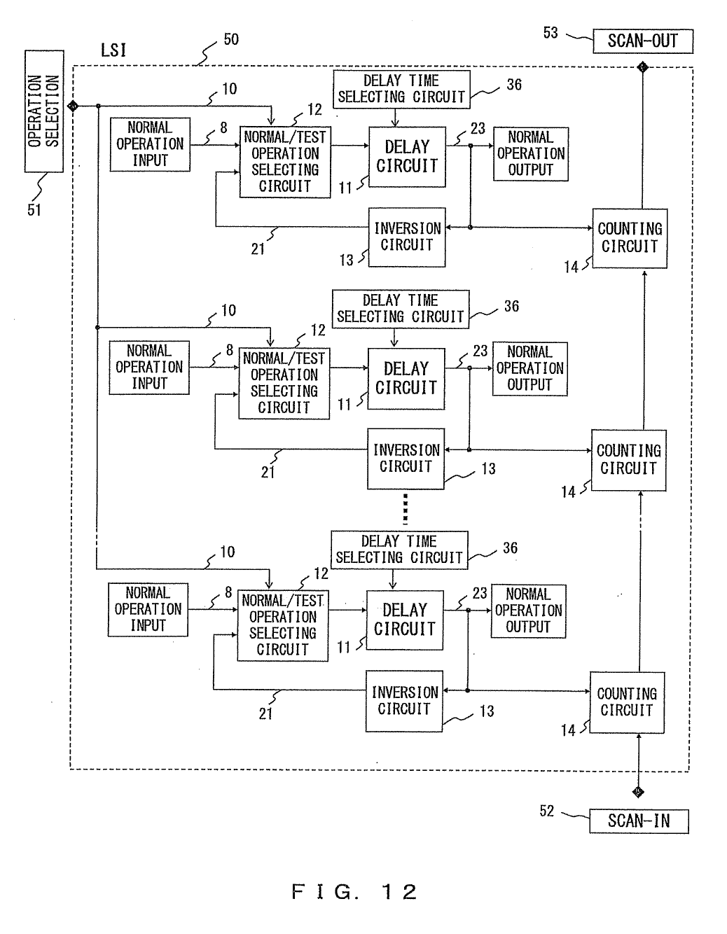

FIG. 12 illustrates a configuration example where a plurality of delay lines according to the embodiments are included in an LSI. Namely, the above described delay circuit (delay line) is configured singly. In contrast, a plurality of delay circuits (delay lines) are included in an LSI in the configuration illustrated in FIG. 12. Although the plurality of delay circuits (delay lines) are included in the LSI 50 as illustrated in FIG. 12, the normal operation input terminal 8, the normal operation output terminal 23, the inversion circuit (inverter) 13, the normal/test operation selecting circuit (selector) 12, the delay time selecting circuit (capacitance value selecting unit) 36, and the counting circuit (counter) 14 are provided for each of the delay circuits (delay lines) 11. Therefore, a test may be conducted for each of the delay lines with the above described methods. However, since the plurality of delay circuits (delay lines) are included in the LSI 50, a delay line 11 selected by an operation selecting unit 51 provided outside the LSI 50 is tested, and the output waveform of the selected delay line 11 is counted by the counting circuit 14. Then the count value is read out with a scan method implementing scan-in 52 and scan-out 53. As described above, a test similar to the above described ones may be conducted even in the configuration where the plurality of delay lines 11 are included in the LSI 50.

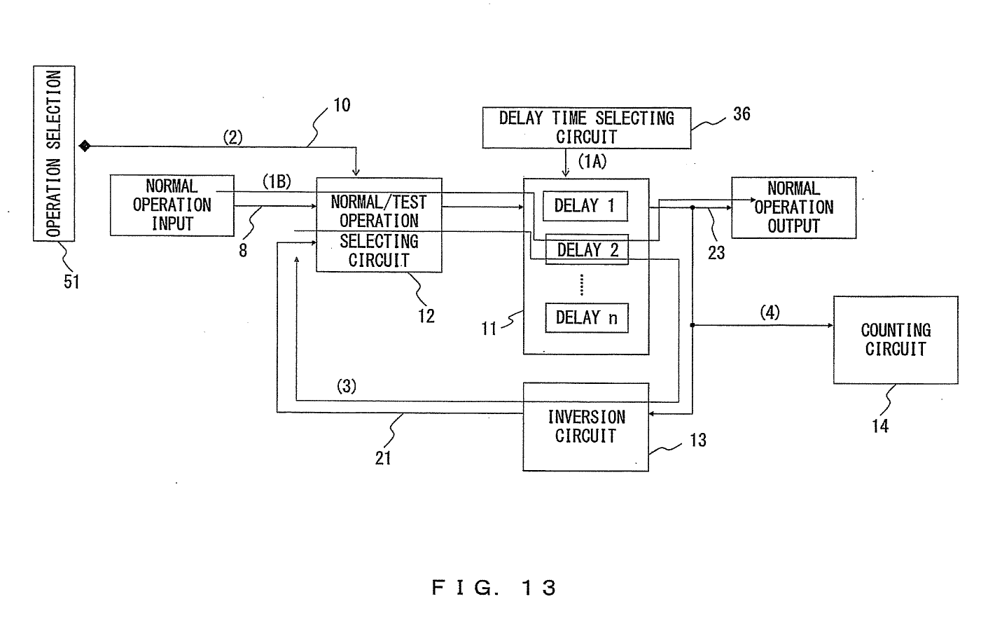

FIG. 13 illustrates an operational sequence for switching between a normal operation and a test operation of the delay circuit according to the embodiments. Assume that the operation of the circuit is currently in the normal operation mode in FIG. 13. Here, a delay time is selected by the delay time selecting circuit 36 (1A). By so doing, the signal is transmitted from the normal operation input 8 to the normal operation output 23 with the delay time set up in the delay circuit 11 (1B). Next, the operation of the delay circuit 11 is switched in accordance with a signal 10 for selecting either of the normal operation and the test operation, which is issued from the operation selecting unit 51 provided outside the LSI (2). By switching the operation of the circuit with the normal/test operation selecting circuit 12, the test operation loop 21 is formed via the inversion circuit 13, and an oscillation waveform at a cycle determined according to the delay time of the delay circuit 11 is output (3). FIG. 13 represents an example that the second delay time is selected in the delay circuit 11. Then, a number determined according to the delay time of the delay circuit 11, namely, a cycle of an input to the counting circuit 14 or the number of inputs is counted (4). The value counted by the counting circuit 14 is read out with the scan method.

According to the configuration and method of the embodiments described above, the number of test input/output terminals is reduced, and a test time is significantly shortened in a functional test. Moreover, an analysis at the time of a fault occurrence is easily made since the state of a delay line is indirectly observed.

Note that the configuration example where a plurality of delay lines according to the embodiments are included in an LSI is also applicable to other functional tests.

As described above, a delay circuit according to the embodiments is configured to be able to select a first signal at the time of a normal operation and a second signal at the time of a test operation. If the first signal is selected, the delay circuit outputs a normal output signal with a selected delay time. In contrast, if the second signal is selected to be input to the delay circuit, an oscillation circuit is configured with a inverting unit to invert the output signal of the delay circuit. An oscillation signal is input to the delay circuit as the second signal, and the output of the delay circuit is provided to a counter, which counts an oscillation waveform. The count value is read out with a scan method. Here, an offset buffer may be inserted in the oscillation circuit in order to enable the measurement of a very small delay time, and a divider is further provided at input side of the counter in order to handle a delay time that broadly ranges in value. As a result, the delay time is measured in a functional manner.

According to the above configuration and method, a functional test can be conducted in a way such that the operation mode of a delay circuit is switched from a normal input to a test input, a delay time is counted by a counter as a digital value, and a scan-out operation is performed for the count value. As a result, test input/output terminals can be reduced, and a test time can be significantly shortened by conducting a functional test. Moreover, an analysis at the time of a fault occurrence can be easily made since the state of the delay circuit can be indirectly observed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions has(have) been described in detail, it should be understood that the various changes, substitutions, and alterations could be made hereto without departing from the spirit and scope of the invention.

What is claimed is:

1. A delay circuit, comprising:
a delay unit configured to delay an input signal and output the delayed signal;
a selecting unit configured to select a first signal at the time of a normal operation or a second signal at the time of a test operation, and provide the selected signal to the delay unit;
an inverting unit configured to invert an output signal of the delay unit, and output the inverted signal as the second signal; and
a counting unit configured to count an output waveform of the delay unit.

2. The delay circuit according to claim 1, further comprising
a control unit configured to control the selecting unit to select the second signal in accordance with a control signal.

3. The delay circuit according to claim 1, further comprising
a dividing unit configured to divide the output signal of the delay unit, and output the divided signal to the counting unit.

4. The delay circuit according to claim 1, wherein
the delay unit comprises
a driver unit for driving a signal, and
a capacitor connected to an output side of the driver unit.

5. The delay circuit according to claim 1, wherein:
the delay unit comprises a plurality of capacitors; and
a delay time of the delay unit is controlled by selecting one or more of the plurality of capacitors.

6. The delay circuit according to claim 5, further comprising
a register unit for storing a set value corresponding to a target delay time, and for outputting the set value to the delay unit, wherein
one or more of the plurality of capacitors are selected according to the set value.

7. The delay circuit according to claim 6, wherein
the register unit further comprises a scan unit, by which the set value is stored.

8. The delay circuit according to claim 1, wherein
the counting unit is configured with a counter having a clock input terminal, to which an output signal of the delay unit is input.

9. The delay circuit according to claim 1, wherein
the counting unit is configured with a counter having a clock input terminal and a count control input terminal, and the output signal of the delay unit is input to the count control input terminal.

10. The delay circuit according to claim 8, wherein
the counter unit comprises a scan unit, by which a count value of the counter unit is read out.

11. A delay circuit, comprising:
a plurality of delay units, to which a plurality of signals being input, configured to delay the plurality of signals and output the delayed signals, respectively;
a plurality of selecting units, provided for each of the delay units, configured to select first signals at the time of a normal operation or second signals at the time of a test operation, and provide the selected signals to the plurality of delay units, respectively;
a plurality of inverting units, provided for each of the delay units, configured to invert output signals of the plurality of delay units, and output the inverted signals as the second signals, respectively; and
a plurality of counting units, provided for each of the delay units, configured to count output waveforms of the plurality of delay units, respectively.

12. A test method for a delay circuit having a delay element for delaying and outputting an input signal, and a selector for selecting a first signal at the time of a normal operation and a second signal at the time of a test operation and for providing the selected signal to the delay element, comprising:
setting a delay time of the delay element;
selecting the second signal by the selector;
generating an oscillation waveform by inverting an output signal of the delay element, and by providing the inverted signal as the second signal; and
counting the oscillation waveform.
